(19) United States
(12) Patent Application Publication
(10) Pub. No.: US 2024/0143983 A1
(43) Pub. Date: May 2, 2024

(54) SNN CIRCUIT STRUCTURE BASED ON THIN FILM TRANSISTOR

(71) Applicant: Pusan National University Industry-University Cooperation Foundation, Busan (KR)

(72) Inventors: Sungsik LEE, Busan (KR); Yeonsu KANG, Busan (KR); Jeongkyun ROH, Busan (KR); Danyoung CHA, Busan (KR); Moonsuk YI, Busan (KR)

(73) Assignee: Pusan National University Industry-University Cooperation Foundation, Busan (KR)

(21) Appl. No.: 18/384,149

(22) Filed: Oct. 26, 2023

(30) Foreign Application Priority Data
Nov. 1, 2022 (KR) 10-2022-0143810

(51) Int. Cl. G06N 3/049; G06N 3/063

(52) U.S. Cl. CPC G06N 3/049; G06N 3/063

(57) ABSTRACT

An SNN circuit structure based on thin-film transistors, includes: a synaptic pass-transistor unit in which a synaptic transistor circuit unit in which N thin-film transistors are connected in parallel is connected to a common pass-transistor load to maintain an output voltage range of the synaptic transistor circuit unit constant; an output circuit unit configured to output a fire signal according to an output signal output from the synaptic pass-transistor unit; and a backpropagation generating transistor unit configured to provide a backpropagation signal transmitted to the synaptic transistor circuit unit with the fire signal output from the output circuit unit as an input.

### CROSS-REFERENCE TO RELATED APPLICATION

This application claims priority to Korean Patent Application No. 10-2022-0143810 (filed on Nov. 1, 2022), which is hereby incorporated by reference in its entirety.

### BACKGROUND

The present invention is related to a Spiking Neural Network (SNN) circuit structure based on thin-film transistors, and more specifically, to an SNN circuit structure based on thin-film transistors that allows a weight adjustment dependent on time-difference input (Spike Timing Dependent Plasticity: STDP), including a thin-film transistor load commonly connected to synaptic thin-film transistors for simultaneously transmitting backpropagation signals according to fire signals for multiple synapses and self-normalizing weights (Synaptic Scaling) to a parallel connection structure of a synaptic pass-transistor.

Homeostasis plasticity is a stabilization mechanism commonly observed in an actual nervous system that allows neurons to maintain activity around their functional operating points. This phenomenon may be used in neuromorphic systems to compensate for slow-changing conditions or chronic changes in system configuration. However, it is important that homeostatic plasticity mechanisms operate on a much longer time scale compared to conventional synaptic plasticity mechanisms in order to avoid interference with other adaptive or learning processes activated in the neuromorphic systems. Synaptic scaling includes scaling synaptic weights of all synapses colliding with neurons globally while maintaining relative differences in order to preserve a learning effect.

Accordingly, as shown in Korean Patent No. 10-2392451 (hereinafter, referred to as Patent Document 0001), in recent years, many attempts have been made to implement a neuromorphic system that simulates synapse of a nervous system using a memristor according to the conventional technology.

On the other hand, the memristor is mainly used with a spike-timing-dependent-plasticity (STDP) in the learning process. Here, STDP is a method of controlling the degree to which a synaptic strength is changed according to a time difference of voltage applied between a pre-neuron and a post-neuron. In the learning process using STDP, since signals are applied to both neurons for learning in different directions, while a signal is being applied in one direction, a signal being applied in the other direction should be stopped. Accordingly, the memristor has difficulty in performing signal processing and learning processes at the same time.

For this reason, attempts have been made to simulate the behavior of synapses using transistors, which are three- or four-terminal devices, rather than two-terminal devices such as memristors. Compared to the existing two-terminal device, by using a transistor device of three or more terminals, it is possible to perform signal processing by voltage between a source (pre-neuron) and a drain (post-neuron) of the transistor and at the same time perform learning to control synapse strength by applying gate voltage.

However, when forming a homeostatic plasticity simulation circuit with three or more transistor devices, there are limitations in terms of area and energy because the increase of the number of synapses and neurons are required to improve learning, and since additional circuitry is required to generate, convert, and transmit signals within the circuit, there is a problem to optimize it.

### PRIOR-ART DOCUMENTS

### Patent Documents

(Patent Document 1) Korean Patent No. 10-2392451 (Apr. 26, 2022)
(Patent Document 2) Korean Patent Application Publication No. 2019-0065145 (Jun. 11, 2019)
(Patent Document 3) Korean Patent No. 10-2218740 (Feb. 16, 2021)
(Patent Document 4) Korean Patent Application Publication No. 2020-0103139 (Sep. 2, 2020)

### SUMMARY

The present invention has been made in consideration of such problems, and the present invention provides an SNN circuit structure based on thin-film transistors that shows that weight adjustment (STDP) of a synaptic transistor is performed according to a time difference input of a signal input to the synaptic transistor and a back-propagation pulse signal through a simple combination of a parallel structure of thin-film transistors and a load of common pass-transistor.

An SNN circuit structure based on thin-film transistors according to embodiments of the present invention includes: a synaptic pass-transistor unit in which a synaptic transistor circuit unit in which N thin-film transistors are connected in parallel is connected to a common pass-transistor load to maintain an output voltage range of the synaptic transistor circuit unit constant; an output circuit unit configured to output a fire signal according to an output signal from the synaptic pass-transistor unit; and a backpropagation generating transistor unit configured to provide a backpropagation signal transmitted to the synaptic transistor circuit unit with the fire signal output from the output circuit unit as an input.

In embodiments of the present invention, the synaptic pass-transistor unit includes a parallel circuit unit configured to represent a synaptic transistor form in which the N thin-film transistors are connected in parallel; and a synaptic scaling unit in which the parallel circuit unit and the common pass-transistor load are connected to maintain an output voltage range of the synaptic transistor constant.

In embodiments of the present invention, the parallel circuit unit receives an input signal or a backpropagation signal input to the synaptic transistor circuit unit, and the backpropagation signal is simultaneously input to each gate or source of the N thin-film transistor devices.

In embodiments of the present invention, in the synaptic scaling unit, the parallel circuit unit is connected to the common pass-transistor load, and the synaptic scaling unit is configured to scale a size of a weight of each synaptic transistor device and maintain a range of an output voltage of the synaptic pass-transistor unit constant.

In embodiments of the present invention, a sum of output voltages of the N synaptic transistor devices is V_{O}, where the V_{O} is Σₘ₌₁ⁿwₘVₘ, where wₘ is

$$\frac{1}{\frac{{R}_{trm}}{{R}_{L}} + {\sum }_{k = 1}^{n} \frac{{R}_{trm}}{{R}_{trk}}} , {R}_{trm}$$

is an equivalent resistance of an m-th synaptic transistor, Rₜᵣₖ is an equivalent resistance of a k-th synaptic transistor, and R_{L} is an equivalent resistance of the pass-transistor load.

In embodiments of the present invention, the synaptic scaling unit is configured to maintain the output voltage range V_{S} of the synaptic pass-transistor unit constant, and the V_{S} is a *(w1+w2+w3)*V_{B1}, where a is a scaling factor, w1, w2, and w3 are weights, and V_{B1} is a bias voltage applied to a drain of the synaptic transistor, and wherein the synaptic scaling unit a common pass-transistor device configured to adjust a level of an output current according to a resistance of the thin-film transistor.

In embodiments of the present invention, the output circuit unit is connected with the synaptic pass-transistor unit, and a membrane potential is accumulated according to an output signal of the synaptic transistor circuit unit, and the output circuit unit includes an output circuit configured to output a fire signal when an accumulated voltage exceeds a reference voltage.

In embodiments of the present invention, the backpropagation generation transistor unit includes a thin-film transistor device configured to output a backpropagation signal transmitted to the output circuit unit, and is configured to output a pulse signal for backpropagation when the fire signal output from the output circuit unit is input.

In embodiments of the present invention, in the backpropagation generation transistor unit, weight adjustment (Spike Timing Dependent Plasticity: STDP) of the synaptic transistor is performed according to a time difference between a pulse signal input to a gate of the synaptic transistor and a pulse signal back-propagated and input to a source.

According to the SNN circuit structure based on thin-film transistors as described above, the following effects are obtained.

First, due to the circuit structure formed by connecting one transistor with respect to multiple synapses, power consumption does not increase even if the number of synaptic devices required increases.

Second, by using one thin-film transistor to transmit a backpropagation signal according to firing to all thin-film synaptic devices at the same time, it is possible to simulate spike timing dependent plasticity (STDP) that adjusts connection strength between neurons in the brain according to backpropagation due to membrane potential changes without a separate biological pathway.

Third, since the circuit structure of the synaptic pass-transistor includes a series connection of a synaptic transistor and a load resistor and can indicate a voltage output directly to the output stage, it has the effect of simulating a biological synapse in which potential signals appear in both input and output more closely than a conventional current-output synaptic device.

Fourth, since the synaptic transistor operates below a threshold voltage, an operating current level of the synaptic pass-transistor is relatively low. In addition, depending on the value of the load resistance connected in series to the synaptic transistor, the level of current flowing through the synaptic pass-transistor and its inversion type and the static power consumption may be relatively low, so the synaptic pass-transistor is expected to be advantageous as an ultra-low-power synaptic device for implementing high-intelligence neuromorphic systems.

### BRIEF DESCRIPTION OF THE DRAWINGS

FIG. 1 is a configuration diagram of the present invention.

FIG. 2 is a circuit diagram of the present invention.

FIG. 3 is a connection circuit diagram of a parallel circuit unit 100a and a synaptic scaling unit 100b according to an embodiment of the present invention.

FIG. 4 is a graph of a weight change according to a pulse signal applied to a gate of the parallel circuit unit 100a when a backpropagation signal pulse is not transmitted to the parallel circuit unit 100a from a backpropagation generation transistor unit 300 according to an embodiment of the present invention.

FIG. 5 is a Spike Timing Dependent Plasticity (STDP) graph when a backpropagation signal pulse is transmitted from the backpropagation generation transistor unit 300 to the parallel circuit unit 100a according to an embodiment of the present invention.

### DETAILED DESCRIPTION

With reference to the accompanying drawings, an SNN circuit structure based on thin-film transistors according to embodiments of the present invention is described in detail. The present invention may be variously modified and may have various forms, and specific embodiments are illustrated in the drawings and described in detail in the description. However, this is not intended to limit the present invention to a specific form of invention, but it should be understood that all modifications, equivalents, or substitutes are included in the scope of idea and technology of the present invention. In describing each drawing, like reference numerals were used for like components. In the accompanying drawings, the dimensions of structures are enlarged than actual for clarity of the present invention or reduced than the actual for the purpose of understanding an approximate configuration.

In addition, terms such as first and second may be used to describe various components, but the components should not be limited by the terms. The terms are used only for the purpose of distinguishing one component from another. For example, without departing the scope of the present invention, a first component may be referred to as a second component, and similarly, the second component may also be referred to as the first component. On the other hand, unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as an ideal or excessively formal meaning unless otherwise defined herein.

The present invention relates to an SNN circuit structure based on thin-film transistors, and more specifically, to an SNN circuit structure based on thin-film transistors that allows weight adjustment according to time difference input (Spike Timing Dependent Plasticity: STDP) including a thin-film transistor load commonly connected to synaptic thin-film transistors, by simultaneously transmitting backpropagation signals according to fire signals for multiple synapses and self-normalizing weights (Synaptic Scaling) to a synaptic pass-transistor parallel connection structure.

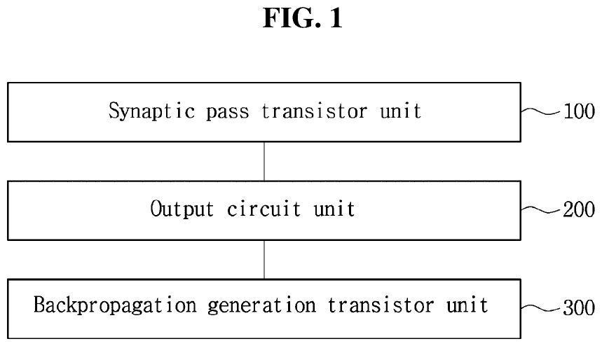

FIG. 1 is a configuration diagram of the present invention.

Referring to FIG. 1, an SNN circuit structure based on thin-film transistors includes a synaptic pass-transistor unit 100, an output circuit unit 200, and a backpropagation generation transistor unit 300. In an embodiment of the present invention, a synaptic transistor circuit unit in which N thin-film transistors are connected in parallel and a common pass-transistor load are connected in the synaptic pass-transistor unit 100 and thus the synaptic pass-transistor unit 100 maintains an output voltage range of the synaptic transistor circuit unit constant. The output circuit unit 200 outputs a fire signal according to an output signal output from the synaptic pass-transistor unit 100. The backpropagation generation transistor unit 300 provides a backpropagation signal transmitted to the synaptic transistor circuit unit with the fire signal output from the output circuit unit 200 as an input. Here, the SNN circuit structure based on thin-film transistors is expected to exhibit ultra-low power characteristics with a low operating voltage and operating current for a synaptic transistor set to operate at a read voltage below a threshold voltage. In addition, by appropriately setting a load resistor limiting the amount of current flowing through the synaptic pass-transistor unit 100, power consumption may be lowered. Therefore, the synaptic pass-transistor (thin-film transistor) according to the present invention may be applied to a high-intelligence neuromorphic system technology as an ultra-low-power voltage-output synaptic device.

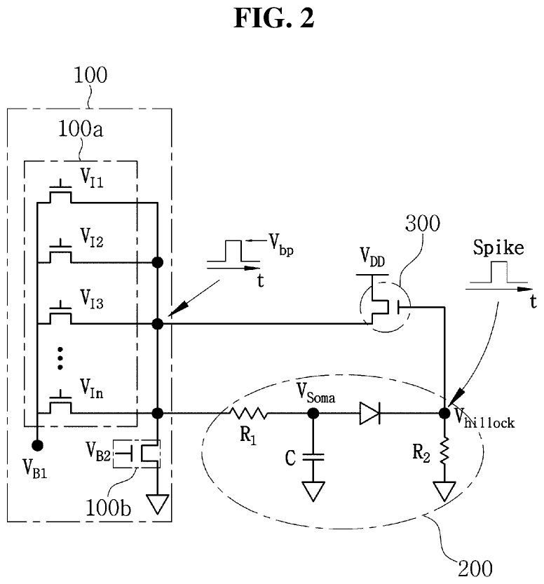

FIG. 2 is a circuit diagram of the present invention.

Referring to FIG. 2, in an embodiment of the present invention, the synaptic pass-transistor unit 100 includes a parallel circuit unit 100a and a synaptic scaling unit 100b. The parallel circuit unit 100a represents a synaptic transistor form in which N thin-film transistors are connected in parallel. The parallel circuit unit 100a and the common pass-transistor load are connected, so the synaptic scaling unit 100b maintains an output voltage range of the synaptic transistor constant.

In an embodiment of the present invention, the parallel circuit unit 100a receives an input signal input to the synaptic transistor circuit unit or a backpropagation signal as input, and the backpropagation signal is simultaneously input to each gate or source of the N thin-film transistor devices. Therefore, using the synaptic transistor, all N thin-film transistor devices receive the backpropagation signal according to firing at the same time, and it is possible to simulate STDP (spike timing dependent plasticity) according to the backpropagation signal due to a change in membrane potential without a separate path like the principle of actual biological neurons. In addition, the parallel circuit unit 100a is connected to a load of the synaptic scaling unit 100b. The synaptic scaling unit 100b maintains a range (0≤V_{S}≤V_{B1}) of an output voltage (V_{S}) of the synaptic pass-transistor unit 100 constant because the parallel circuit unit 100a is connected to the common pass-transistor load, and the synaptic scaling unit 100b maintains a sum of output voltages of the N synaptic transistor devices constant and scales the size of a weight of each synaptic transistor device.

The output circuit unit 200 is connected to one end of the synaptic pass-transistor unit 100 and a membrane potential is accumulated according to an output signal of the synaptic transistor circuit unit (the parallel circuit unit 100a), and the output circuit unit 200 includes an output circuit for outputting the fire signal when an accumulated voltage exceeds a reference voltage VB1. In addition, the backpropagation generation transistor unit 300 includes a thin-film transistor element for outputting the backpropagation signal transmitted to the output circuit unit 200, and when the fire signal output from the output circuit unit 200 is input, a pulse signal for backpropagation is output. In addition, weight adjustment (STDP) of the synaptic transistor is performed according to a time difference between a pulse signal input to a gate of the synaptic transistor and a pulse signal back-propagated and input to a source of the synaptic transistor.

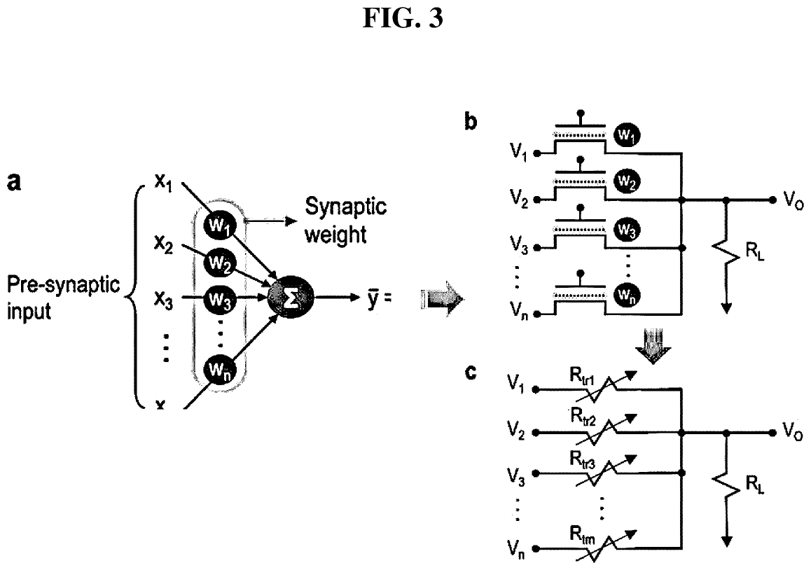

FIG. 3 is a connection circuit diagram of the parallel circuit unit 100a and the synaptic scaling unit 100b according to an embodiment of the present invention.

Referring to FIG. 3, the synaptic pass-transistor unit 100 includes the parallel circuit unit 100a connected to the common pass-transistor load, and scales the size of the weight of each synaptic transistor device to maintain the range of the output voltage of the synaptic pass-transistor unit 100 constant. In other words, to explain in more detail,

According to an embodiment of the present invention, the synaptic pass-transistor unit 100 includes a common pass-transistor device for adjusting the level of the output current according to a resistance of the thin-film transistor. Here, the output voltage V_{S} of the synaptic pass-transistor unit 100 is kept constant, and the V_{S} may be expressed as a*(w1+w2+w3)*V_{B1}, where a is a scaling factor, w1, w2, and w3 are weights, and V_{B1} is a bias voltage applied to a drain of the synaptic transistor. Here, the scaling factor a and W1, W2, and W3 keep the range of V_{S} constant through adjustment of the weights. (i.e., 0≤V_{S}≤V_{B1}, between 0 and 1), The range of V_{S} between 0≤V_{S}≤V_{B1} is kept constant. Here, the sum of the output voltages of the N synaptic transistor devices of the synaptic pass-transistor unit 100 is V_{O}, where the V_{O} is Σₘ₌₁ⁿwₘ Vₘ, where wₘ is

$$\frac{1}{\frac{{R}_{trm}}{{R}_{L}} + {\sum }_{k = 1}^{n} \frac{{R}_{trm}}{{R}_{trk}}} ,$$

Rₜᵣₘ: an equivalent resistance of the m-th synaptic transistor, Rₜᵣₖ: an equivalent resistance of the k-th synaptic transistor, and R_{L}: an equivalent resistance of the pass-transistor load. However, V_{O} is a sum of output voltages of N thin-film transistors, a is the weight, and the output voltage range V_{S} is not defined as a constant or variable. Therefore, when the self-normalization (synaptic scaling=homeostatic scaling) is implemented by connecting the neuron synaptic transistor and the common pass-transistor load, the range of the output voltage is kept constant even if the number of respective thin-film transistors increases. Further, at this time, since the resistance value of the common pass-transistor load is a fixed value, there is an advantage that the maximum power consumption does not increase even when the number of thin-film transistors increases.

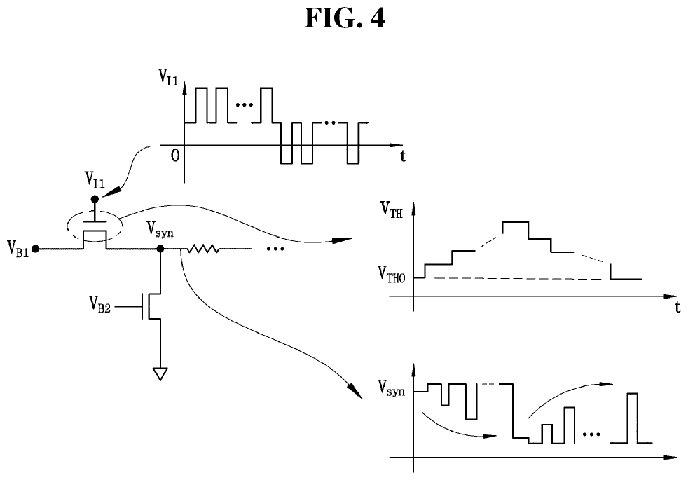

FIG. 4 is a graph of a weight change according to a pulse signal applied to a gate of the parallel circuit unit 100a when a backpropagation signal pulse is not transmitted to the parallel circuit unit 100a from the backpropagation generation transistor unit 300 according to an embodiment of the present invention.

Referring to FIG. 4, the synaptic scaling unit 100b utilizes a difference between a voltage input value and a backpropagation voltage input to the neuron synaptic transistor in which the N thin-film transistors are connected in parallel to adjust the connection strength of the neuron circuit. Here, when the backpropagation signal pulse from the backpropagation generating transistor unit 300 is not transmitted to the parallel circuit unit 100a, scaling is performed by a pulse signal applied to the gate of the parallel circuit unit 100a. In other words, the neuron synaptic transistor is connected with a common pass-transistor load (R_{L}) and the synaptic scaling unit 100b maintains the sum of the output voltages of N thin-film transistors constantly, and scales the size of the weight to realize self-normalization (synaptic scaling=homeostatic scaling). Here, scaling controls the increase or decrease of V_{S} by only adjusting the a and the weights of w1, w2, and w3 in a formula such as a*(w1+w2+w3)*V_{B1}, and the range of output that can be expressed as 0≤V_{S}≤V_{B1} in the above formula remains constant. Accordingly, the sum of each weight (w1+w2+w3) is scaled by the factor a, and its range is also maintained between 0 and 1.

Therefore, in the case of self-normalization (synaptic scaling=homeostatic scaling), even if the number of connected thin-film transistor devices increases, a memory state of each thin-film transistor device determining the weight is maintained. According to a relationship of resistance magnitude between the thin-film transistor devices, the current level flowing through each thin-film transistor device is scaled so that the output voltage appears within a predetermined range. In other words, a potential difference between the input and output of the thin-film transistor device is not kept constant, but the range of voltage represented by the sum of the output voltages of the thin-film transistor devices remains constant.

Therefore, the threshold voltage Vth, which is determined by the amount of electrons trapped in the thin-film transistor device, does not change, but only the current level is scaled, so that the size relationship of weights between the synaptic pass-transistors also does not change.

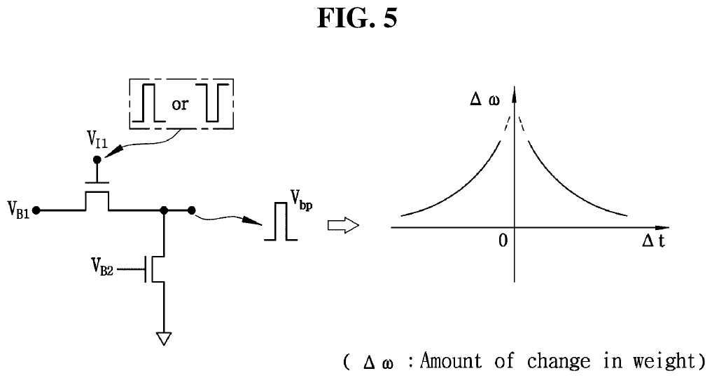

FIG. 5 is a spike timing dependent plasticity (STDP) graph when a backpropagation signal pulse is transmitted from the backpropagation generation transistor unit 300 to the parallel circuit unit 100 according to an embodiment of the present invention.

Referring to FIG. 5, the synaptic scaling unit 100b utilizes the difference between the voltage input value and the backpropagation voltage input to the neuron synaptic transistor in which N thin-film transistors are connected in parallel to adjust the connection strength of the neuron circuit.

Here, the backpropagation generation transistor unit 300 includes a transistor device for outputting a backpropagation signal transmitted to the parallel circuit unit 100a, and using the fire signal output from the output circuit unit 200 as an input, turn on the transistor device for outputting the backpropagation signal. During the turn-on of the transistor device for outputting the backpropagation signal, the backpropagation generation transistor unit 300 generates and transmits a pulse signal according to the backpropagation signal having a time difference with the pulse signal input to the neuron synaptic transistor. To explain in more detail, while the transistor used for transmitting the backpropagation signal is turned on by a spike signal, it can be seen that an electrical pulse appears in the parallel circuit unit 100a. At this time, the weight change as shown in the drawing may be confirmed according to the time difference between the pulse signal applied to the parallel circuit unit 100a and the pulse indicated by the backpropagation. The backpropagation signal is simultaneously applied to the neuron synaptic transistors connected in parallel, rather than separately transmitted to the N thin-film transistors.

Therefore, reactivity in which the STDP occurs may vary depending on randomness of the device characteristics that may appear in a manufacturing process or operation process of each of the N thin-film transistors. Due to these characteristics, an inverted synaptic pass-transistor circuit structure can be taken. In other words, to explain in more detail, in the synaptic pass-transistor including a series connection of a synaptic transistor and a load resistor and in which an output voltage appears at a source terminal according to another embodiment of the present invention, as an input voltage is applied to a drain terminal of the synaptic transistor and a read or programming voltage is applied to a gate terminal, an output voltage appears at the source terminal of the synaptic transistor to which the load resistor is connected. The synaptic transistor operates in a region below the threshold voltage, and electrons are trapped or de-trapped in the charge trap depending on whether the sign of the programming voltage applied to the gate terminal is positive (+) or negative (−). Accordingly, the threshold voltage and equivalent resistance of the synaptic transistor increase or decrease, and the output voltage appear at the source terminal for the input voltage applied to the drain terminal. Here, the ratio between the output voltages is a synaptic weight.

As mentioned above, the present invention scales the output current of the neuron mimetic device to maintain the threshold voltage of the neuron mimetic device constant through a simple combination of the parallel structure of the thin-film transistor and the common pass-transistor to provide an SNN circuit structure based on thin-film transistors that represents spike timing dependent plasticity (STDP) of neurons. Therefore, according to the SNN circuit structure based on thin-film transistors as described above, the following effects are obtained. First, due to the circuit structure formed by connecting one transistor to multiple synapses, power consumption does not increase even if the number of synaptic devices required increases. Second, by using one thin-film transistor to transmit a backpropagation signal according to firing to all thin-film synaptic devices at the same time, it is possible to simulate spike timing dependent plasticity (STDP) that adjusts connection strength between neurons in the brain according to backpropagation due to membrane potential changes without a separate biological pathway. Third, since the circuit structure of the synaptic pass-transistor includes a series connection of a synaptic transistor and a load resistor and can indicate a voltage output directly to the output stage, it has the effect of simulating a biological synapse in which potential signals appear in both input and output more closely than the conventional current-output synaptic device. Fourth, since the synaptic transistor operates below a threshold voltage, so an operating current level of the synaptic pass-transistor is relatively low, and depending on the value of the load resistance connected in series to the synaptic transistor, the level of current flowing through the synaptic pass-transistor and its inversion type and the resulting static power consumption may be relatively low, the synaptic pass-transistor is expected to be advantageous as an ultra-low-power synaptic device for implementing high-intelligence neuromorphic systems.

Although the detailed description of the present invention described above refers to the preferred embodiments of the present invention, it will be understood that a person skilled in the art or having ordinary knowledge in the art can make various modifications and changes to the present invention without departing from the spirit and technical scope of the present invention as described in the appended claims.

[Explanation of Symbols]

| | |
|---|---|
| 100: Synaptic pass-transistor unit | 100a: Parallel circuit unit |
| 100b: Synaptic scaling unit | 200: Output circuit unit |
| 300: Backpropagation generation transistor unit | |

What is claimed is:

1. An SNN circuit structure based on thin-film transistors comprising:
a synaptic pass-transistor unit in which a synaptic transistor circuit unit in which N thin-film transistors are connected in parallel is connected to a common pass-transistor load to maintain an output voltage range of the synaptic transistor circuit unit constant;
an output circuit unit configured to output a fire signal according to an output signal output from the synaptic pass-transistor unit; and
a backpropagation generating transistor unit configured to provide a backpropagation signal transmitted to the synaptic transistor circuit unit with the fire signal output from the output circuit unit as an input.

2. The SNN circuit structure of claim 1, wherein the synaptic pass-transistor unit comprises:
a parallel circuit unit configured to represent a synaptic transistor form in which the N thin-film transistors are connected in parallel; and
a synaptic scaling unit in which the parallel circuit unit and the common pass-transistor load are connected to maintain an output voltage range of the synaptic transistor constant.

3. The SNN circuit structure of claim 2, wherein the parallel circuit unit receives an input signal or a backpropagation signal input to the synaptic transistor circuit unit, and
the backpropagation signal is simultaneously input to each gate or source of the N thin-film transistor devices.

4. The SNN circuit structure of claim 2, wherein, in the synaptic scaling unit, the parallel circuit unit is connected to the common pass-transistor load, and
the synaptic scaling unit is configured to scale a size of a weight of each synaptic transistor device and
maintain a range of an output voltage of the synaptic pass-transistor unit constant.

5. The SNN circuit structure of claim 4, wherein a sum of output voltages of the N synaptic transistor devices is V_{O},
where the V_{O} is Σₘ₌₁ⁿwₘ Vₘ, where wₘ is
$$\frac{1}{\frac{{R}_{trm}}{{R}_{L}} + {\sum }_{k = 1}^{n} \frac{{R}_{trm}}{{R}_{trk}}} ,$$
Rₜᵣₘ is an equivalent resistance of an m-th synaptic transistor, Rₜᵣₖ is an equivalent resistance of a k-th synaptic transistor, and R_{L} is an equivalent resistance of the pass-transistor load.

6. The SNN circuit structure of claim 3, wherein the synaptic scaling unit is configured to maintain the output voltage V_{S} of the synaptic pass-transistor unit constant, and
the V_{S} is a*(w1+w2+w3)*V_{B1},
where a is a scaling factor, w1, w2, and w3 are weights, and V_{B1} is a bias voltage applied to a drain of the synaptic transistor, and
wherein the synaptic scaling unit a common pass-transistor device configured to adjust a level of an output current according to a resistance of the thin-film transistor.

7. The SNN circuit structure of claim 1, wherein the output circuit unit is connected to one end of the synaptic pass-transistor unit, and
a membrane potential is accumulated according to an output signal of the synaptic transistor circuit unit, and
wherein the output circuit unit comprises an output circuit configured to output a fire signal when an accumulated voltage exceeds a reference voltage.

8. The SNN circuit structure of claim 1, wherein the backpropagation generation transistor unit comprises a thin-film transistor device configured to output a backpropagation signal transmitted to the output circuit unit, and
is configured to output a pulse signal for backpropagation when the fire signal output from the output circuit unit is input.

9. The SNN circuit structure of claim 8, wherein, in the backpropagation generation transistor unit,
weight adjustment (Spike Timing Dependent Plasticity: STDP) of the synaptic transistor is performed according to a time difference between a pulse signal input to a gate of the synaptic transistor and a pulse signal back-propagated and input to a source.
